(19) United States
(12) Patent Application Publication
(10) Pub. No.: US 2001/0031406 A1
(43) Pub. Date: Oct. 18, 2001

(54) Photomask and exposure method

(75) Inventor: Takashi Masuyuki, Kawasaki-shi (JP)

Correspondence Address: OLIFF & BERRIDGE, PLC, P.O. Box 19928, Alexandria, VA, 22320, US

(73) Assignee: Nikon Corporation

(21) Appl. No.: 09/737,598

(22) Filed: Dec. 18, 2000

Related U.S. Application Data
(63) Continuation of application No. 09/181,820, filed on Oct. 29, 1998, now abandoned.

(30) Foreign Application Priority Data
Oct. 30, 1997 (JP) 09-316307

(51) Int. Cl. G03F 9/00

(52) U.S. Cl. 430/22; 430/5

(57) ABSTRACT

A mask pattern of one device row in which a plurality of device patterns are arranged in its longitudinal direction is placed on a mask. A wafer is stepped so that the mask pattern and a photosensitive substrate are moved relative to each other in a short-side direction perpendicular to the longitudinal direction, and the device row is successively transferred onto the photosensitive substrate. A plurality of device rows transferred onto the photosensitive substrate in this manner are arranged in the short-side direction.

### BACKGROUND OF THE INVENTION

1. Field of the Invention

The present invention relates to a method for manufacturing microdevices, such as thin film magnetic heads, and also relates to an exposure method of projecting device patterns onto a photosensitive substrate by exposure, and a photomask on which the device patterns are formed.

2. Description of the Related Art

In a conventional exposure method of the above type, a reticle pattern in which a large number of device patterns are arranged in the form of a matrix is drawn on a projection plate, such as a mask or reticle, and the reticle pattern is projected by exposure onto a photosensitive substrate, such as a wafer or a glass plate, that is coated with a photosensitive material, such as a resist. (In the present specification, the projection plate will be generally called “reticle”, and the photosensitive substrate will be generally called “wafer”.)

When overlay exposure is performed in which a second reticle pattern is laid over and projected by exposure onto a first reticle pattern that has been transferred to a wafer by exposure, array coordinate values of selected ones or all of shots over the entire area of the first reticle pattern are measured, and the overlay position of the second reticle pattern is calculated based on the measurement values, so as to perform the exposure operation.

Where the reticle used for the exposure operation includes device patterns arranged in an almost square shape, however, the array of device patterns within the exposure pattern formed on the wafer suffers from greatly reduced straightness, due to distortion of a projection optical system, shot rotation, error arising during fabrication of reticles, variations in the shot magnification, and so forth, and the thus reduced straightness is difficult to correct.

At the time of overlay exposure, too, overlaid exposure patterns are not necessarily projected by exposure in the correct positions, if the array of the device patterns is carefully observed for each column or each row.

### SUMMARY OF THE INVENTION

The first object of the present invention is to provide an exposure method that enables a multiplicity of device patterns to be arranged on a photosensitive substrate with high accuracy, by forming an exposure pattern that contains only stepping error of an exposure apparatus.

The second object of the present invention is to provide an exposure method by which overlay exposure is performed, assuring highly accurate alignment of device array for each column or each row.

The third object of the present invention is to provide a photomask that is suitably used in an exposure apparatus, so that a multiplicity of device patterns are arranged on a photosensitive substrate with high accuracy.

The fourth object of the invention is to provide a method for manufacturing microdevices with high accuracy, by a photolithography process in which a multiplicity of device patterns are formed on a photosensitive substrate.

In the first exposure method according to the present invention, a mask pattern is placed on a projection plate, which mask pattern is designed such that a plurality of device patterns are arranged in a longitudinal direction thereof, and a row of devices or a small number of rows of devices are arranged in a short-side direction thereof, and stepping exposure is performed to project the mask pattern on a photosensitive substrate by exposure, at such a pitch that does not allow overlap of mask patterns in the short-side direction, thereby to form an exposure pattern consisting of a plurality of exposure shots, on the photosensitive substrate. This method can avoid reduction in the array accuracy of the device patterns, due to errors arising upon drawing of the mask pattern, shot rotation, and other factors.

In the first exposure method as described above, the plurality of device patterns arranged in one device row may be identical with each other, or different from each other. When a plurality of device rows are formed in the short-side direction, the device patterns of each device row may be identical with each other, or different from each other.

The second exposure method of the present invention includes: a first step of placing a first mask pattern on a projection plate, the first mask pattern being designed such that a plurality of device patterns are arranged in a longitudinal direction thereof, and a row of devices or a small number of rows of devices are arranged in a short-side direction thereof, and performing stepping exposure to project the first mask pattern on a photosensitive substrate by exposure, at such a pitch that does not allow overlap of first mask patterns in the short-side direction, thereby to form a first exposure pattern consisting of a plurality of exposure shots; a second step of measuring coordinate values of at least two exposure shots that constitute the first exposure pattern; a third step of calculating an array error parameter based on measurement values of the two or more exposure shots, and designed array coordinate values, and determining array coordinate values of the exposure shots in the first exposure pattern, based on the array error parameter and the designed array coordinate values; and a fourth step of laying a second mask pattern over the first exposure pattern to project the second mask pattern on the first exposure pattern by exposure, based on the array coordinate values determined in the third step, the second mask pattern being designed such that a plurality of device patterns are arranged in a longitudinal direction thereof, and a row of devices or a small number of rows of devices are arranged in a short-side direction thereof. With this method, errors in the array of the device patterns that may be caused by drawing errors of the first mask pattern can be significantly reduced, and the second mask pattern can be accurately laid over and transferred onto each exposure shot in the first exposure pattern.

In the second exposure method, the plurality of device patterns arranged in one device row of either the first or second reticle pattern may be identical with each other, or different from each other. Where a plurality of device rows are formed in the short-side direction, the device patterns of each device row may be identical with each other, or different from each other.

The present invention also provide a photomask used for transferring device patterns onto a substrate, which includes a pattern row in which at least two device patterns are arranged in a longitudinal direction thereof. The two or more device patterns arranged in the single pattern row may be identical with each other, or different from each other. The use of the photomask as described above can significantly reduce errors in the array of device patterns due to drawing errors of the mask pattern, shot rotation, and others. Where the device patterns are those for producing magnetic heads, in particular, each column of device patterns may be cut out in the short-side direction from the numerous device patterns formed on the substrate, to provide a substrate slip, and end faces of the substrate slip that extend in the short-side direction may be polished (ground). In this case, too, the device patterns are arranged in each column with high accuracy, which leads to a reduced number of defective in the device patterns (magnetic heads) that are individually cut out from the substrate slip after grinding.

In the photomask according to the present invention, a specific pattern may be formed in series with the pattern row as viewed in the longitudinal direction, and the specific pattern may include alignment marks that are respectively located at opposite ends of the pattern row, such that the pattern row is interposed between the alignment marks. Also, another pattern row may be formed on the photomask to extend in parallel with the above pattern row. The use of this photomask can reduce exposure processing time (pattern transfer time) of the substrate, while reducing errors in the array of device patterns that are caused by drawing errors of the mask pattern, and other factors. The device patterns contained in each pattern row may be identical with each other, or different from each other.

In the third exposure method of the present invention, a plurality of pattern rows in each of which a plurality of device patterns are arranged in a longitudinal direction thereof are transferred onto a substrate in a short-side direction perpendicular to the longitudinal direction. The plural device patterns arranged in one pattern row may be identical with each other, or different from each other. This method can significantly reduce errors in the array of device patterns that may be caused by pattern drawing errors of the photomask, or rotation of the pattern row during transferring.

In the third exposure method as described above, the plurality of pattern rows that are arranged in the short-side direction may be transferred onto each of a plurality of regions on the substrate. In overlay exposure in which a second pattern row is transferred onto each of the pattern rows that have been transferred to one of the plurality of regions, the second pattern row and the substrate may be moved relative to each other, based on position information obtained by detecting a plurality of marks formed in the above-indicated one region. To improve product throughput, in particular, it is preferable to calculate a parameter of a function that represents an array of the plurality of pattern rows is calculated, based on the obtained position information, and array position information of the pattern rows is determined using the parameter.

In the third exposure method as described above, the second pattern row may be laid over and transferred onto each of the patterns rows in each of the regions, after a plurality of marks are detected in each region. Alternatively, the second pattern row may be laid over and transferred onto each of the pattern rows that has been transferred to one of the plurality of regions, after a plurality of marks are detected in the above-indicated one region. Preferably, the device patterns are used for producing magnetic heads. Since the numerous device patterns formed on the substrate are arranged with high accuracy, the number of defective in the device patterns (magnetic heads) cut out from the substrate can be considerably reduced. In a further form of the invention, another pattern row may be formed in parallel with the above pattern row. In this case, the device patterns of each pattern row may be identical with each other, or different from each other.

The present invention also provides a method for manufacturing microdevices, wherein a plurality of pattern rows in each of which a plurality of device patterns are arranged in a longitudinal direction thereof are transferred onto a substrate, in a short-side direction perpendicular to the longitudinal direction, and each column of the device patterns thus transferred is cut out in the short-side direction. Here, the plural device patterns arranged in one pattern row may be identical with each other, or different from each other. With the manufacturing method as described above, the plurality of device patterns transferred onto the substrate are arranged with high accuracy, thus enabling each column of the device patterns to be cut out from the substrate in the short-side direction. Therefore, various processes may be performed after the exposure process, with respect to each column of device patterns, resulting in reduced process time. For example, the substrate slip corresponding to each column of device patterns has end faces that extend in the short-side direction, and the end faces are polished (ground) after the exposure process. The individual device patterns are then cut out from the substrate slip whose end faces have been ground.

In the method for manufacturing microdevices according to the present invention, the device patterns are preferably those for magnetic heads, in which case magnetic heads are produced as microdevices. In this case, the fraction defective in the magnetic heads cut out from the substrate slip after grinding can be considerably reduced. In a further form of the invention, another pattern row may be formed on the photomask in parallel with the above-indicated pattern row. In this case. the device patterns contained in each pattern row may be identical with each other, or different from each other.

### BRIEF DESCRIPTION OF THE DRAWINGS

FIG. 1(a) is a plan view showing a reticle used in an exposure method according to the present invention.

FIG. 1(b) is a plan view showing an exposure pattern formed on a wafer.

FIG. 1(c) is a plan view showing a device block that is cut out from the wafer.

FIG. 2(a) is a view useful in explaining reduction of error with a reduction in the lens diameter of a projection optical system.

FIG. 2(b) is a view useful in explaining reduction of error that occur during fabrication of reticles.

FIG. 2(c) is a view useful in explaining reduction of error due to shot rotation.

FIG. 3(a) is a flowchart showing a sequence of overlay exposure according to the first embodiment of the present invention;

FIG. 3(b) is a flowchart showing a sequence of overlay exposure according to the second embodiment of the present invention;

FIG. 3(c) is a flowchart showing a sequence of conventional overlay exposure.

FIG. 4 is a plan view showing a wafer that is mounted on a water holder on an X-Y stage.

FIG. 5(a) is a view useful in explaining rotational error of the wafer;

FIG. 5(b) is a view useful in explaining the orthogonality of an array coordinate system

FIG. 5(c) is a view useful in explaining expansion of the wafer in x direction and y direction.

FIG. 5(d) is a view useful in explaining offsets of the wafer in the x direction and y direction.

FIG. 6(a) is a view useful in explaining conventional overlay exposure.

FIG. 6(b) is a view useful in explaining overlay exposure of the present invention.

FIG. 7(a) is a view useful in explaining the arrangement of alignment marks of exposure shots used in the overlay exposure of the present invention.

FIG. 7(b) is a view showing the arrangement of alignment marks of exposure shots that is different from that of FIG. 7(a).

### DESCRIPTION OF THE PREFERRED EMBODIMENTS

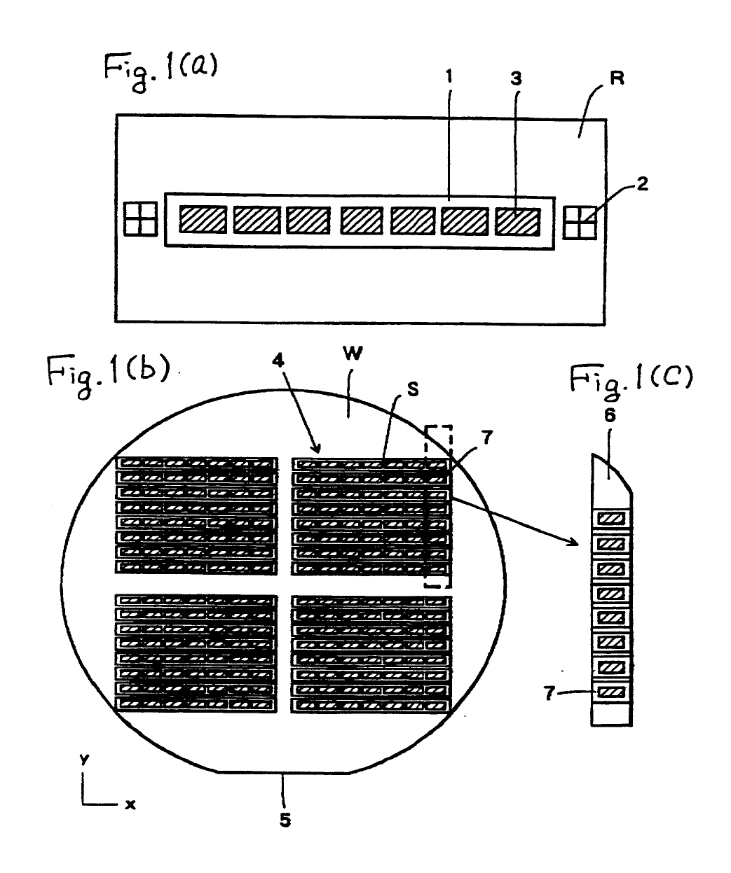

An exposure method according to one embodiment of the present invention will be described. As shown in FIG. 1(a), a reticle pattern 1 and alignment marks 2 are formed on a reticle R, such that the alignment marks 2 are disposed in series with the reticle pattern 1 as viewed in a direction of extension (longitudinal direction) of the pattern 1. The reticle pattern 1 includes a plurality of identical or different device patterns 3 (seven patterns in FIG. 1(a)) that are arranged in the longitudinal direction. By performing so-called stepping exposure, namely, successively projecting the reticle R by exposure onto the wafer W at such a pitch that does not allow overlap of projected patterns, an exposure pattern as shown in FIG. 1(b) is formed on the wafer W. Here, the stepping direction lies in the direction of the short side of the device pattern 3 (i.e., y direction in the figure). To transfer the reticle pattern 1 onto the wafer W, substantially the entire area of the reticle pattern 1 is irradiated with illumination light for exposure while the reticle R and the wafer W are almost at rest, and the wafer W is exposed to the illumination light through the reticle R. Thus, so-called one-time exposure type (stationary exposure type) exposure apparatus (stepper) is used in the present embodiment, wherein the reticle pattern 1 is transferred in a step-and repeat mode, over substantially the entire area of the wafer W.

While FIG. 1(a) shows only a single row of patterns (row of devices) in which a plurality of device patterns 3 are arranged in the longitudinal direction, a plurality of rows of patterns may be formed in the short-side direction of the device pattern 3, such that the pattern rows extend in parallel with each other. In this case, the device patterns of each pattern row may be identical with each other, or different from each other. If the number of rows of patterns arranged in the short-side direction is increased, however, the array accuracy of the device patterns on the wafer W may deteriorate due to errors arising during pattern drawing, and other factors. Thus, the number of rows of patterns is determined by finding the compromise between the exposure processing time of the wafer W (throughput of the exposure apparatus), and the array accuracy of the device patterns. For instance, another row of patterns may be formed in parallel with the pattern row as shown in FIG. 1(a), so as to avoid a reduction in product throughput while at the same time reducing errors in the array of device patterns. If the throughput is allowed to be reduced, it is most desirable to provide a single row of patterns.

While the alignment marks 2 are formed at the opposite ends of the device patterns 3 (reticle pattern 1) in FIG. 1(a) such that the patterns 3 are interposed between the marks 2, only one alignment mark may be formed at one end of the reticle pattern 1. Also, alignment marks may be formed at the opposite ends of the reticle pattern 1 as viewed in the short-side direction of the device patterns 3, or only one alignment mark may be formed at one end of the reticle pattern 1 as viewed in the same direction. These alignment marks may be formed on the reticle R in addition to the alignment marks 2 shown in FIG. 1(a), or in place of the alignment marks 2. It is, however, most desirable to form the alignment marks 2 at the opposite ends of the reticle pattern I as viewed in the longitudinal direction, as shown in FIG. 1(a), so that the marks 2 may be used for detection of rotational errors of the reticle pattern 1 transferred onto the wafer W.

The stepping exposure is performed with respect to each of a plurality of partitioned regions on the wafer W. In the present embodiment, the wafer W having a diameter of 3 inches is divided into 2×2 regions, and the exposure pattern 4 is formed on each of these regions. For each of the regions, a plurality of blocks each including one column of device patterns are cut out from the exposure pattern 4 formed on the wafer W, in the stepping direction of the wafer W (short-side direction of the device pattern 3). After opposite end faces of each of the device blocks (substrate slips) 6 that extend in the short-side direction of the device patterns 3 are polished (ground), individual devices 7 are cut out one by one from the device block 6.

In the exposure method of the present embodiment, the same reticle pattern 1 is projected by exposure on one shot S at a time, while making parallel movement above the wafer W. As a result, the device patterns 3 formed at the same location on the reticle pattern 1 are arranged in the stepping direction. Therefore, all of the device patterns contained on each of the device blocks 6 cut out in the stepping direction are physically identical, and the straightness of the devices 7 arranged in the cut-out direction is determined only by the stepping accuracy (array accuracy) of the exposure apparatus. Thus, the straightness of the devices in each column can be considerably improved. Accordingly, the exposure method of the present embodiment is most suitably employed for fabrication of magnetic heads, or the like, since the device performance of the magnetic heads often fluctuates due to variations in the dimensions between cutting faces and the devices. In this connection, ceramic wafers are used in fabrication of magnetic heads.

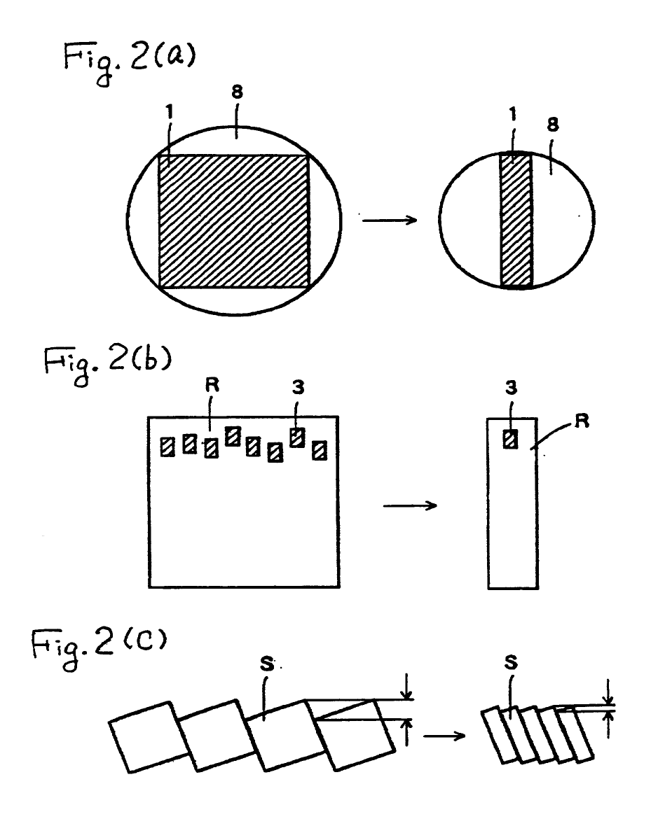

In the exposure method of the present embodiment, since the drawing area of the reticle pattern 1 can be reduced, the following advantageous features can be provided as well as reduced cost of manufacture of reticles. The advantageous features provided by the exposure method of the invention will be explained with reference to FIG. 2(a) through FIG. 2(c), wherein the left-hand side of each figure indicates the case of a conventional exposure method, and the right-hand side indicates the case of the exposure method of the present embodiment.

First, a circular projection field of view (namely, the diameter of a lens, or its equivalent) can be set to be small, as shown in FIG. 2(a). With the reduction in the projection field of view, the lens distortion can be limited to a small level, and the size of a projection lens can be reduced, which leads to a reduction in the size of the exposure apparatus as a whole, and a reduction in the manufacturing cost.

Secondly, errors that occur during manufacture of reticles (errors in pattern drawing) can be reduced, as shown in FIG. 2(b). In the manufacture of reticles in which electron beams are generally used, a reticle substrate tens to expand under an influence of heat generated during pattern drawing using an electron beam. If the drawing area is small, therefore, the irradiation time of the electron beam is shortened, and the heat generated by the electron beam is reduced, resulting in reduced manufacturing errors caused by expansion of the reticle substrate.

Thirdly, an exposure pattern area of each shot S is reduced, and error due to shot rotation is reduced accordingly, as shown in FIG. 2(c).

The number of the devices arranged on the reticle R in the short-side direction is not limited to one, but may be adequately determined, taking account of the fact that as the number of the devices is increased, product throughput is improved, but the accuracy in fabrication of reticles deteriorates.

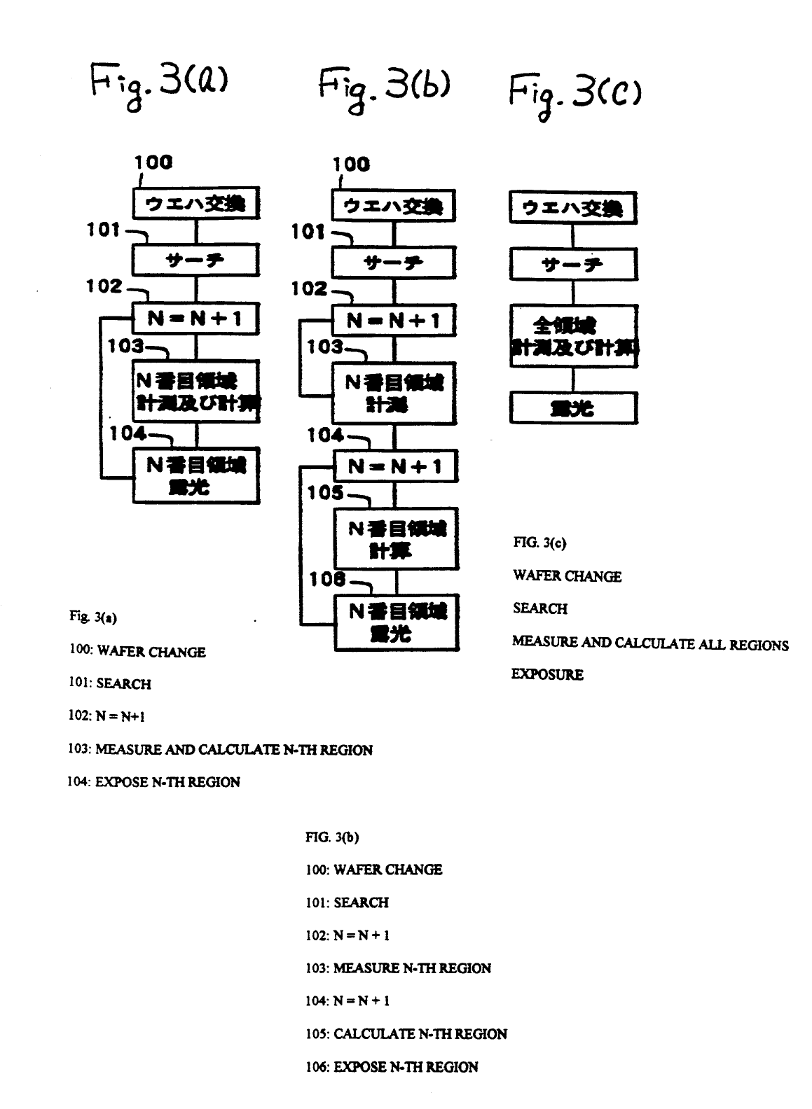

Next, overlay exposure according to the present invention will be explained, referring to FIG. 3(a) showing the first example of sequence or flow of control that is used for the overlay exposure of the present invention.

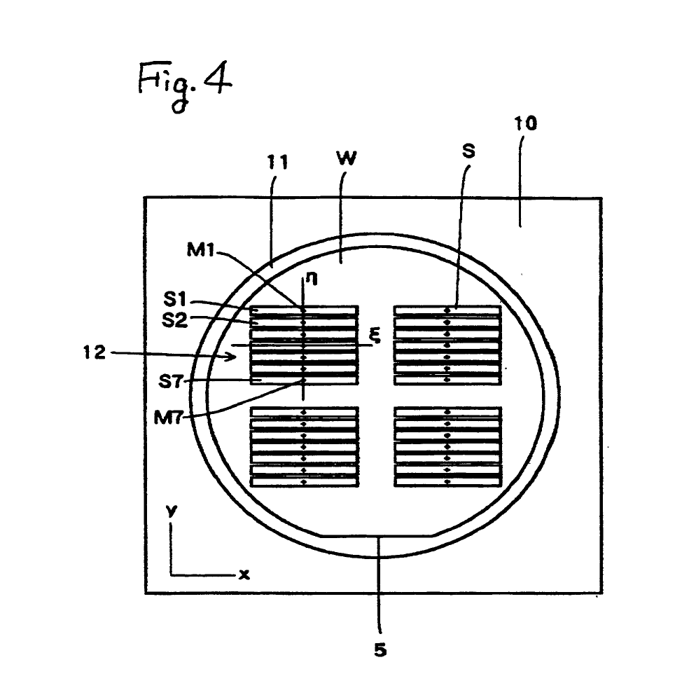

Initially, step 100 is executed to place a wafer W on an X-Y stage 10. The wafer W on which the first exposure pattern is already formed by the exposure method as described above is subjected to subsequent processing steps (such as a development process), and then fed back to the exposure apparatus. In this step, the wafer W is mounted on a wafer holder 11 such that a straight notch (orientation flat) 5 of the wafer W extends substantially in parallel with the x axis of the X-Y stage 10, as shown in FIG. 4. The wafer holder 11, which sucks the wafer W under vacuum, is disposed on the X-Y stage that is movable two-dimensionally in the x direction and y direction, such that the holder 11 is rotatable by minute angles relative to the X-Y stage 10.

In step 101, search alignment is performed for aligning the wafer W with the X-Y stage 10. The first exposure pattern 12 is formed in each of four regions on the wafer W that correspond to the first to fourth quadrants, respectively. Assuming that an array coordinate system ε-η having orthogonal axes ε and η is placed on the wafer W, exposure shots S that constitute the first exposure pattern 12 are arranged one-dimensionally for each region, along the array coordinates system ε-η. Here, the e axis of the array coordinate system ε-η is set to be in parallel with the orientation flat 5.

Suppose search alignment is performed using the first exposure pattern 12 located in the second quadrant of the wafer. The exposure shots S1-S7 that constitute the first exposure pattern 12 are provided with respective alignment marks M1-M7. With respect to the exposure shots S1, S7 located at the opposite ends of the exposure shots S1-S7, the coordinates values of the corresponding marks M1, M7 are measured by an alignment detection system that is not illustrated. An angular deviation of the array coordinate system ε-η from the coordinate system x-y on which the X-Y stage 10 is moved is calculated based on the coordinate values measured by the alignment detection system, and the wafer holder 11 is rotated so that the orientation of the array coordinate system ε-η substantially coincides with that of the coordinate system x-y.

In the search alignment, however, errors occur between the array positions of the exposure shots S in the first exposure pattern 12 and the array coordinate values as designed, due to insufficient accuracy of the alignment detection system, and shifts in the array positions of the exposure shots during processing steps after exposure. In the overlay exposure, therefore, a device pattern 7 may not be accurately aligned with the first exposure pattern 12, according to the designed array coordinate values (positions on the x-y coordinate system). Namely, error may occur between the array position of the first exposure pattern 12 and the designed array coordinate values, depending upon such factors as; rotation of the wafer W, the degree of orthogonality of the array coordinate system ε-η, expansion of the wafer W in the x direction and y direction, and offsets of the wafer W in the x direction and y direction.

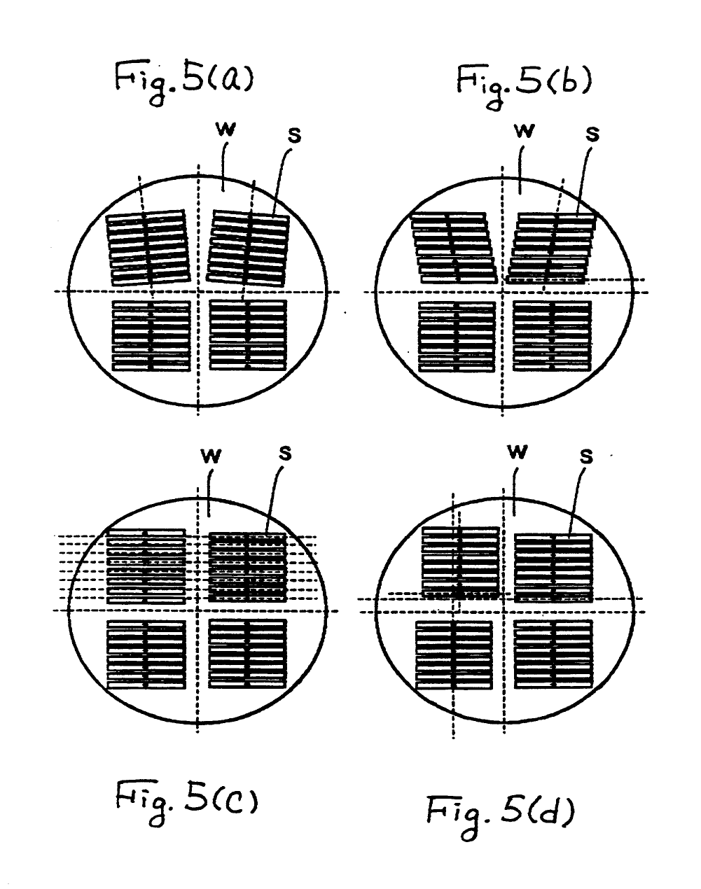

The error arising from rotation of the wafer W is caused by measurement error of the alignment detection system, and others, when the wafer holder 11 is rotated so as to coincide the array coordinate system ε-η with the coordinate system x-y, as shown in FIG. 5(a). This type of error is represented by the remaining angular deviation θ of the array coordinate system ε-η from the coordinate system x-y.

As shown in FIG. 5(b), the error that depends upon the orthogonality of the x-y coordinate system is caused by lack of accurate orthogonality in the feed directions of the X-Y stage 10, and error in mounting mirrors (inclination of mirrors) that reflect beams of interferometers provided on the X-Y stage 10. This type of error is represented by orthogonality error amount “w”.

As shown in FIG. 5(c), the error due to expansion of the wafer W in the ε (x) direction and η (y) direction results from expansion of the wafer W as a whole under an influence of heat and others during processing of the wafer W. This type of error is evident particularly in the peripheral portion of the wafer W, and represented by Rx, Ry for the ε (x) direction and η (y) direction, respectively, where Rx represents the ratio of an actual measurement value to a design value of the distance between two points on the wafer W in the ε (x) direction, and Ry represents the ratio of an actual measurement value to a design value of the distance between two points on the wafer W in the η (y) direction.

As shown in FIG. 5(d), the error due to offsets in the x direction and y direction results from deviations of the wafer W as a whole in the x direction and y direction, depending upon the detection accuracy of the alignment detection system, positioning accuracy of the wafer holder, and others. This type of error is represented by Ox, Oy for the x direction and y direction, respectively.

In view of the above situations, it is necessary to perform enhanced global alignment (EGA), so as to obtain array coordinate values based on which each exposure shot S should be actually positioned. The EGA technology is disclosed, for example, in Japanese laid-open Patent Publication (Kokai) No. 61-44428 (and corresponding U.S. Pat. No. 4,780,617), and therefore will be only briefly described in this specification. In the present embodiment, EGA is performed with respect to each region on which the first exposure pattern 12 is formed. Namely, step 102-103 of the above sequence are executed to measure array coordinate values of a plurality of exposure shots S in the first exposure pattern 12, for each region of the wafer W, and calculate errors between the measured coordinate values of the exposure shots S and designed array coordinate values.

Initially, coordinates F*n (F*xn, F*yn) of at least two of the exposure shots S1-S7 of each region, for example, those of at least two exposure shots including the exposure shots S1, S7 located at the opposite ends of the region, are measured. In the present embodiment, shot coordinates F*1 (F*x1, F*y1) and F*7 (F*x7, F*y7) of the exposure shots S1, S7 of each region are measured.

Where Dn (Dxn, Dyn) represent designed position coordinates of each exposure shot S in the first exposure pattern 12, and Fn (Fxn, Fyn) represent shot coordinates based on which each of the shots should be actually positioned during overlay exposure, in view of the above-described errors, the shot coordinates Fn (Fxn, Fyn) are expressed using the designed position coordinates Dn (Dxn, Dyn) as follows.

Fn=A·Dn+O (1)

where,

$$\begin{matrix}Fn = ( \begin{matrix}Fxn \\ Fyn\end{matrix} ) & ( 2 ) \\ A = ( \begin{matrix}Rx & - Rx ( w + θ ) \\ Ry \cdot θ & Ry\end{matrix} ) & ( 3 ) \\ Dn = ( \begin{matrix}Dxn \\ Dyn\end{matrix} ) & ( 4 ) \\ O = ( \begin{matrix}Ox \\ Oy\end{matrix} ) & ( 5 )\end{matrix}$$

Here, “A” represents an error parameter related to rotation of the wafer W, orthogonality of the array coordinate system ε-η, and expansion of the wafer W in the x direction and y direction, and “O” represents an error parameter related to offsets in the x direction and y direction.

Then, address error (=F*n−Fn), namely, positional deviations of the actually measured shot coordinates F*n (F*xn, F*yn) from the shot coordinates Fn (Fxn, Fyn) based on which the shot should be positioned, is calculated. With regard to the obtained address error En, the error parameters A, O are determined so as to minimize the address error En, using the least square method.

Using the error parameters A, O thus determined, the shot coordinates Fn (Fxn, Fyn) are calculated with respect to all of the exposure shots S1-S7 contained in one region (exposure pattern 12) according to the above equation (1), and the array coordinate values of the exposure shots S1-S7 located in this region are determined. Subsequently, the X-Y stage 10 is moved according to the array coordinate values thus determined, and a second reticle pattern is laid over and transferred onto each exposure shot of the first exposure pattern 12. The second reticle pattern has exactly the same structure as the reticle pattern 1 as shown in FIG. 1(a), and is formed on a second reticle that is different from the reticle 1 only in that the device patterns of the second reticle pattern are different from the device patterns 3 of the reticle pattern 1.

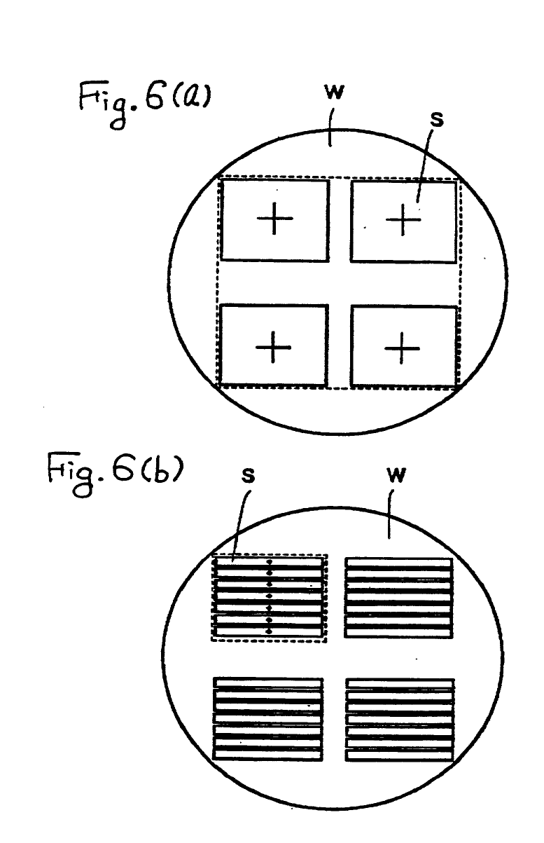

In conventional overlay exposure, EGA is performed according to the sequence as shown in FIG. 3(c), with respect to the whole region of the wafer W (as defined by a broken line in FIG. 6(a)) in which the exposure shots S are arranged as shown in FIG. 6(a). In the exposure method of the present invention, on the other hand, EGA is performed on a region (as defined by a broken line in FIG. 6(b)) in which the position of each exposure shot S in the array is determined only by the stepping accuracy of the exposure apparatus, as shown in FIG. 6(b). Accordingly, only linear error is contained in the address error involved in each region on which EGA is performed, and therefore the address error can be more precisely calculated. Furthermore, the overlay exposure as described above is performed with respect to each region as described above, thus assuring considerably high alignment accuracy.

FIG. 3(b) shows a second example of sequence used for overlay exposure of the present invention. In the sequence used for performing EGA according to the first embodiment of the exposure method as described above, coordinate values of at least two exposure shots within one region are measured, and array coordinate values of all of the exposure shots S1-S7 are respectively calculated based on the measurement results. The reticle R and wafer W are moved relative to each other based on the calculated coordinate values, and the second reticle pattern is laid over and transferred onto each exposure shot. A series of these steps is then repeated with respect to N regions (4 regions in FIG. 4). In the sequence according to the second embodiment of the exposure method, on the other hand, steps 102-103 are executed to measure coordinate values of at least two exposure shots in each of all of the N regions, and steps 104-106 are executed to calculate coordinate values of the exposure shots S1-S7 for each region, based on the measured shot coordinate values. The following step of performing overlay exposure using the second reticle pattern is then repeated with respect to each of the exposure shots S1-S7.

In the sequence of the present embodiment, the step of measuring shot coordinate values with respect to all of the regions is executed separately from the step of calculating the shot coordinate values and performing overlay exposure. In this manner, the overall exposure time can be shortened.

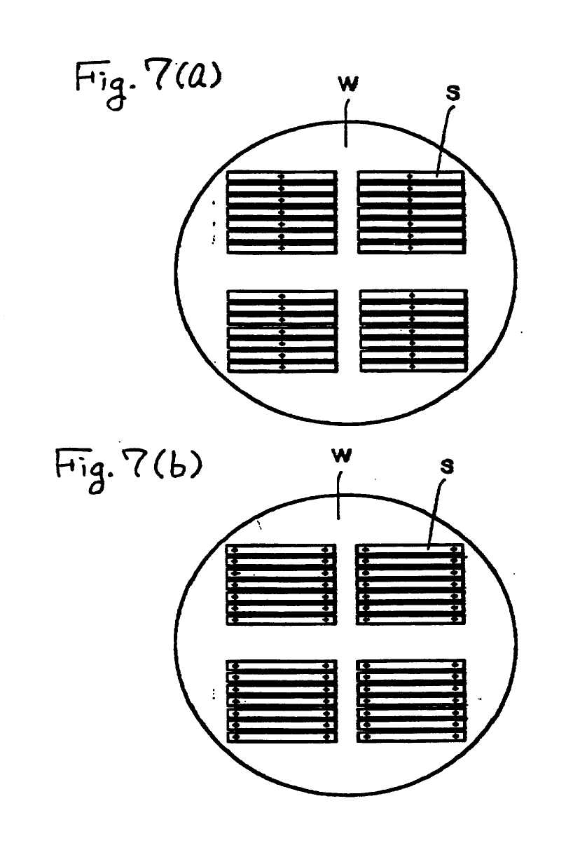

In the EGA as described above, coordinate values of each exposure shot S are measured using one alignment mark affixed thereon, as shown in FIG. 7(a). It is, however, possible to form a plurality of alignment marks on each of the exposure shots S, as shown in FIG. 7(b), and perform so-called multi-point measurement during EGA so that the coordinate values of each of the exposure shots S are determined based on measurement values of at least two alignment marks. In this case, the measurement values of the two or more alignment marks may be averaged, and the average value thus obtained may be used. As another method, weights may be given to the two or more measurement values, and the average value of the weighed measurement values may be used. By using the multi-point measurement as described above, error can be reduced owing to the effect of averaging of the measurement values, and thus the overlay accuracy is effectively improved. In the present example, two alignment marks are formed on each of the exposure shots S.

The fabrication of thin film magnetic heads includes a step of designing the function and performance of magnetic heads, a step of producing a reticle based on the design, in the manner as explained in the illustrated embodiments, a step of forming a wafer of a ceramic material, a step of exposing the wafer to image light carrying a reticle pattern by the exposure method of the illustrated embodiments, an assembling step (including a dicing process, grinding process, and a packaging process), and an inspection step.

Instead of using the exposure apparatus of step-and-repeat type, scanning exposure apparatus of step-and-scan type as disclosed in Japanese laid-open Patent Publication (Kokai) No. 4-196513 (and corresponding U.S. Pat. No. 5,473,410) and Japanese laid-open Patent Publication (Kokai) No. 4-277612 (and corresponding U.S. Pat. No. 5,194,893) may be used. In the scanning exposure apparatus, it is desirable to coincide the direction of movement of the reticle relative to illumination light for exposure, with the direction (short-side direction of the device pattern 3) perpendicular to the direction of extension of the reticle pattern 1 (longitudinal direction of the device pattern 3) as shown in FIG. 1(a), for example. Where the number of rows of patterns arranged in the short-side direction on the reticle is small, the scanning exposure apparatus may not be particularly used.

According to the present invention as described above, it is possible to produce an exposure pattern that contains only stepping error that occurs during exposure of the exposure apparatus.

When the overlay exposure is performed, coordinate values of at least two exposure shots are measured in one region in which the array accuracy of the exposure shots is determined only by the stepping accuracy of the exposure apparatus. Then, address error is obtained with respect to each of the exposure shots whose coordinate values were measured, and the coordinate values of all of the exposure shots in this region are determined using the address error. In this manner, the overlay exposure position of the exposure shot in each row or each column can be determined with considerably high accuracy, and therefore the mask pattern can be laid over the exposure shot with high accuracy. Consequently, the devices can be arranged with high straightness, which leads to a reduction in the percent defective that would otherwise increase due to variations in the array of the devices. The exposure method of the present invention, therefore, is particularly suitably applied to the fabrication of magnetic heads.

Furthermore, the projection field of view (or the size of an optical component) of the projection optical system can be reduced, and the size and cost of the exposure apparatus can be reduced accordingly.

In addition, the drawing area of the reticle can be reduced, thus making it possible to reduce the cost of manufacture of reticles.

It is to be understood that the present invention is not limited to the illustrated embodiments, but may be otherwise embodied with various changes or modifications, without departing from the principle of the present invention.

All of the disclosures of Japanese Patent Application No. 9-229152 filed Oct. 30, 1997, including the specification, claims, drawings and abstract, are herein incorporated by reference.

What is claimed is:

1. An exposure method comprising the steps of: placing a mask pattern on a projection plate, said mask pattern being designed such that a plurality of device patterns are arranged in a longitudinal direction thereof, and a row of devices or a small number of rows of devices are arranged in a short-side direction thereof; and performing stepping exposure to project the mask pattern on a photosensitive substrate by exposure, at such a pitch that does not allow overlap of mask patterns in the short-side direction, thereby to form an exposure pattern comprising a plurality of exposure shots, on the photosensitive substrate.

2. An exposure method according to claim 1, wherein said exposure pattern is formed on said photosensitive substrate in each of a plurality of regions thereof that do not overlap with each other.

3. An exposure method comprising:
a first step of placing a first mask pattern on a projection plate, said first mask pattern being designed such that a plurality of device patterns are arranged in a longitudinal direction thereof, and a row of devices or a small number of rows of devices are arranged in a short-side direction thereof, and performing stepping exposure to project the first mask pattern on a photosensitive substrate by exposure, at such a pitch that does not allow overlap of first mask patterns in the short-side direction, thereby to form a first exposure pattern comprising a plurality of exposure shots, on the photosensitive substrate;
a second step of measuring coordinate values of at least two exposure shots that constitute said first exposure pattern;
a third step of calculating an array error parameter based on measurement values of said at least two exposure shots, and designed array coordinate values, and determining array coordinate values of the exposure shots in the first exposure pattern, based on the array error parameter and the designed array coordinate values; and
a fourth step of laying a second mask pattern over said first exposure pattern to project the second mask pattern on the first exposure pattern by exposure, based on the array coordinate values determined in said third step, said second mask pattern being designed such that a plurality of device patterns are arranged in a longitudinal direction thereof, and a row of devices or a small number of rows of devices are arranged in a short-side direction thereof.

4. An exposure method according to claim 3, wherein said first exposure pattern is formed on said photosensitive substrate in each of a plurality of regions thereof that do not overlap with each other, and said second step, said third step and said fourth step are repeated for each of said plurality of regions.

5. An exposure method according to claim 3,
wherein said first exposure pattern is formed on said photosensitive substrate in each of a plurality of regions thereof that do not overlap with each other, and said second step is executed with respect to all of said plurality of regions, and
wherein said third step and said fourth step are repeated for each of said plurality of regions.

6. A photomask used for transferring device patterns onto a substrate, comprising:
a pattern row in which at least two device patterns are arranged in a longitudinal direction thereof.

7. A photomask according to claim 6,
wherein said device patterns are those for producing magnetic heads.

8. A photomask according to claim 6, further comprising a specific pattern formed in series with said pattern row as viewed in the longitudinal direction.

9. A photomask according to claim 8, wherein said specific pattern comprises alignment marks that are respectively located at opposite ends of said pattern row, such that the pattern row is interposed between the alignment marks.

10. A photomask according to claim 6, further including another pattern row that is located in parallel with said pattern row.

11. An exposure method wherein a plurality of pattern rows in each of which a plurality of device patterns are arranged in a longitudinal direction thereof are transferred onto a substrate in a short-side direction perpendicular to the longitudinal direction.

12. An exposure method according to claim 11, wherein said plurality of pattern rows that are arranged in said short-side direction are transferred onto each of a plurality of regions on said substrate.

13. An exposure method according to claim 12, wherein another pattern row and said substrate are moved relative to each other, based on position information obtained by detecting a plurality of marks formed in one of said plurality of regions, so that said another pattern row is laid over and transferred onto each of said plurality of pattern rows that have been transferred onto said one of said plurality of regions.

14. An exposure method according to claim 13, wherein a parameter of a function that represents an array of said plurality of pattern rows is calculated, based on the obtained position information, and array position information of said plurality of pattern rows is determined using said parameter.

15. An exposure method according to claim 13, wherein said another pattern row is laid over and transferred onto each of said plurality of patterns rows in each of said plurality of regions, after said plurality of marks are detected in each of said plurality of regions.

16. An exposure method according to claim 13, wherein said another pattern row is laid over and transferred onto each of said plurality of pattern rows that have been transferred onto said one of said plurality of regions, after said plurality of marks are detected in said one of said plurality of regions.

17. An exposure method according to claim 11, wherein said device patterns are those for producing magnetic heads.

18. A method for manufacturing microdevices, comprising the steps of: transferring a plurality of pattern rows in each of which a plurality of device patterns are arranged in a longitudinal direction thereof, onto a substrate, in a short-side direction perpendicular to the longitudinal direction; and cutting out each column of said plurality of device patterns thus transferred, in the short-side direction.

19. A method for manufacturing microdevices according to claim 19, further comprising the step of grinding end faces of a substrate slip cut out from said substrate, said end faces extending in said short-side direction.

20. A method for manufacturing microdevices according to claim 19, further comprising the step of cutting out said device patterns one by one, from said substrate slip whose end faces have been ground.

21. A method for manufacturing microdevices according to claim 18, wherein said device patterns are those for magnetic heads that are manufactured as the microdevices.
